(19) United States
(12) Patent Application Publication
(10) Pub. No.: US 2023/0252329 A1
(43) Pub. Date: Aug. 10, 2023

(54) Method and System for Analyzing the Cause of Faults in a Process Engineering Installation

(71) Applicant: Siemens Aktiengesellschaft, Muenchen (DE)

(72) Inventors: Thomas BIERWEILER, Karlsruhe (DE); Daniel LABISCH, Karlsruhe (DE); Erion SYLA, Karlsruhe (DE)

(21) Appl. No.: 18/013,097

(22) PCT Filed: Jun. 29, 2021
(86) PCT No.: PCT/EP2021/067918

§ 371 Date: Dec. 27, 2022

(30) Foreign Application Priority Data
Jun. 30, 2020 (EP) 20183283

(51) Int. Cl. G06N 7/01; G01M 99/00; G06F 30/18

(52) U.S. Cl. CPC G06N 7/01; G01M 99/005; G06F 30/18

(57) ABSTRACT

A method and system for analyzing the cause of faults in a process engineering installation, wherein engineering information of the engineering installation, where the information contains information about the engineering installation components as well as their interconnection in the engineering installation, is provided in digital form in order to use the engineering information to create an inference model in the form of a probabilistic physical model of the engineering installation with probability distributions and prior variables, where measurement data from the engineering installation are used to perform Bayesian inference of fault probabilities during a diagnosis mode of the inference model.

### CROSS-REFERENCE TO RELATED APPLICATIONS

This is a U.S. national stage of application No. PCT/EP2021/067918 filed 29 Jun. 2021. Priority is claimed on European Application No. 20183283.9 filed 30 Jun. 2020, the content of which is incorporated herein by reference in its entirety.

### BACKGROUND OF THE INVENTION

### 1. Field of the Invention

The invention relates to a system and method for root cause analysis in a process engineering plant.

### 2. Description of the Related Art

Automation engineering is used to automate engineering processes. The overall automated system consists of a plant in which the process runs, an automation system and operating personnel. The plant can in particular be a process engineering or chemical engineering plant operating in the fields of the chemical industry, the food and beverage industry, environmental technology industry, the pharmaceutical industry or the gas and oil industry.

Such an (industrial) plant generally comprises a plurality of individual interconnected plant components. Typical plant components of a chemical engineering or process engineering plant are vessels, reactors, piping, and/or fittings, through which, for example, starting materials, in particular fluids, pass during a manufacturing process and are thereby changed or processed to produce a resulting product.

At the process-oriented field level of the automation system, locally distributed decentralized field devices perform specified functions within the scope of plant automation and thereby exchange information relevant to the process, plant and/or device with automation components of the higher-ranking levels of the automation system. The field devices include sensors (measuring transducers for, for example, level, flow rate, pressure and temperature, analyzers for analyzing gases or liquids, weighing systems), which transmit process data as measured values of process variables, and actuators (actuating drives, positioners for valves other decentralized regulators and frequency converters for electromotive drives of, for example, pumps), which receive process data as actuating data to influence the process.

There is a general need to optimize the efficiency of such plants and to reduce deviations of the values of individual process variables from setpoint values, and thus from the plant's operating point, in order to stabilize the operation of the plant to better comply with quality requirements or to operate the process closer to its limits and increase throughput.

However, certain critical deviations cannot be eliminated by regulation systems alone, but require additional counter measures. If these faults are not detected in time, then the result can be poor product quality or even the failure of plant components, plant parts or even the complete plant.

As it detects fault situations more quickly, automated fault diagnosis enables the timely initiation of countermeasures in order to shorten or even prevent downtimes. The object of fault diagnosis (fault detection and isolation (FDI)) is, on the one hand, the detection of faults and, on the other, the isolation of individual fault types in order to narrow down the cause of the fault.

Methods for fault diagnosis are frequently divided into two categories. On the one hand, there are process-model-based methods that insert the measured signals into a mathematical model and calculate characteristic variables. On the other hand, there are also signal-based data-driven methods, which create a black box model of the plant or analyze correlations based on historical data [1, pages 5-6].

Model-based approaches are divided into state estimators, such as extended Kalman filters or unknown input observers (UIOs), which estimate the most likely operational or fault state in the state space, parity equations, which exploit analytical redundancy by additional sensors in order to generate characteristic residual signatures, or parameter estimation methods that determine deviating parameter values and assign each deviation to a fault source [2, page 9].

Signal-based methods follow different approaches. Limit tests or vibration signal models, which test signals individually for deviations in values or frequencies are sufficient for simple signals, whereas statistical classification methods or artificial intelligence are used for more complex systems. Static methods reduce the order of the system with methods such as principal component analysis (PCA) by determining the minimum number of independent components and then performing cluster analysis. Machine learning algorithms, on the other hand, optimize numerous parameters of a neural network or decision tree on recorded training data [3, pages 41-43].

The methods mentioned only give an overview of the subject area since literature in this field has pursued many different approaches, in particular in recent years. So far, no single method has proven to be superior to others, which is why there has been an increasing trend for research to be performed in many directions [4, pages 4-5].

Model-based approaches require extensive system understanding, which is frequently not available for chemical engineering processes. The processes considered are frequently non-linear, dynamic, hybrid and complex which enormously increases not only the modeling effort, but also the computing effort, in particular for large industrial plants [1.]. Therefore, solutions from other areas cannot be simply transferred. Likewise, strong noise in measurements falsifies the results.

Process knowledge is frequently available in the form of measurement data. Consequently, data-driven approaches are more frequently pursued in the process industry sector. Herein, principal component analysis (PCA) and projection to latent structures (PLS) are particularly widespread among statistical methods [5, page 267] and artificial neural networks (ANN) and support vector machines (SVM) as learning methods [6, pages 4-5]. Here, the advantages are the very low effort required for implementation and the possibility for using them as a complete solution from the measured value to the fault type.

However, frequently no or little data on fault situations is available and plant operators are reluctant to put their plant into critical situations to obtain this data. In this situation, purely signal-based models fail because, even if they can identify an unknown fault and distinguish it from the rest of the faults, they cannot assign the fault to a specific component or malfunctions.

### SUMMARY OF THE INVENTION

In view of the foregoing, it is therefore an object of the invention to provide a system and method for combining model-based and signal-based methods in a hybrid approach to maximize their advantages and reduce their disadvantages.

This and other objects and advantages are achieved in accordance with the invention by a method for root cause analysis in a process engineering plant, where engineering information on the plant, which contains information about the plant components and their interconnection in the plant, is provided in digital form, an inference model in the form of a probabilistic physical model of the plant with probability distributions and prior variables is created from the engineering information and Bayesian inference of fault probabilities is performed in a diagnosis mode of the inference model with the inference model using measurement data from the plant.

The objects and advantages in accordance with the invention is further achieved by a system for root cause analysis in a process engineering plant with a transformation module, which is configured to create an inference model in the form of a probabilistic physical model of the plant with probability distributions and prior variables from engineering information on the plant, which contains information about the plant components and their interconnection in the plant, and with an inference module, which is configured to perform Bayesian inference of fault probabilities in a diagnosis mode of the inference model using measurement data from the plant.

Here, engineering information designates planning data for the process engineering plant and the plant structure and component data, which is stored in plant planning software such as COMOS or can be obtained from data sheets. The engineering information can in particular be a machine-readable piping and instrumentation flow diagram (P&I) flow diagram that contains all relevant components of the plant and the automation as graphic objects.

In a training mode of the inference model, estimates of model parameters representing priors in the inference model can be optimized by performing Bayesian inference of the inference model using measurement data from the plant.

The inference model can advantageously be created from the engineering information using a bond graph. Bond graphs are suitable for analyzing mechatronic systems because they provide a standardized representation of a plurality of engineering domains. Since process engineering plants consist not only of hydraulic piping systems and mechanical actuators, but also of electrical circuits and information technology data flows, such a representation is very advantageous for identifying a wide variety of fault types. In addition, the bond graph theory provides a formalism for analyzing the P&I flow diagram that can be used in an automated system.

First, a metamodel of the plant can be generated from the engineering information on the plant, in particular the P&I flow diagram, by adopting templates from a model library that contains the code to be generated and inference variables for each component type in the plant for which Bayesian inference is to be performed. The inference model of the plant can then be created from the metamodel using a recursive function, for example.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The following explains the invention with reference to exemplary embodiments and with reference to the figures in the drawing, in which:

FIG. 1 is schematic illustration of an engineering plant in which actuators and sensors interact in accordance with the invention;

FIG. 2 is an exemplary flow diagram of the method in accordance with the invention;

FIG. 3 is a schematic illustration of a class diagram of the transformation module in accordance with the invention;

FIG. 4 is a schematically simplified bond graph with a block diagram;

FIG. 5 is a schematic illustration of the plant structure of the metamodel;

FIG. 6 a simple example of a factor graph in accordance with the invention;

FIG. 7 is a class diagram of the inference module in accordance with the invention;

FIG. 8 is an illustration of variable types of the base class of the inference module;

FIG. 9 is an example of model programming in accordance with the invention;

FIG. 10 is an illustration of a factor graph of the plant during training of the inference model in accordance with the invention; and

FIG. 11 is an illustration of the factor graph during fault cause diagnosis.

### DETAILED DESCRIPTION OF THE EXEMPLARY EMBODIMENTS

The same reference symbols have the same meaning in the different figures. The representations are purely schematic and do not represent any size ratios.

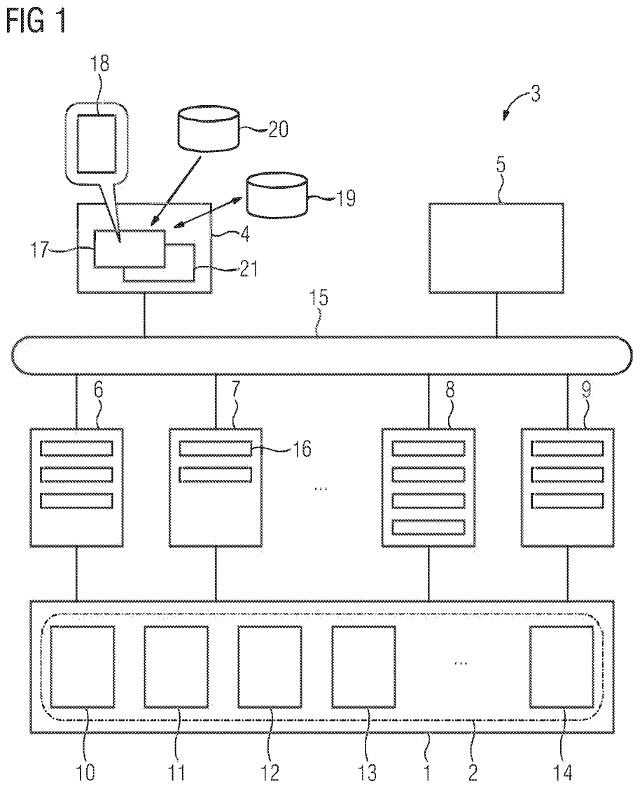

FIG. 1 is a simplified schematic representation of an exemplary process engineering plant 1 in which a process 2 is controlled via an automation system 3. The automation system 3 contains a planning and engineering system 4, an operating and observation system 5, a plurality of automation devices 6, 7, 8, 9 and a plurality of field devices 10, 11, 12, 13, 14. The planning and engineering system 4, the operating and observation system 5 and the automation devices 6, 7, 8, 9 are connected to one another via a bus system 15. The field devices 10, 11, 12, 13, 14 are connected to the automation devices 6, 7, 8, 9 in different ways, such as directly, via field buses or a decentralized periphery, and perform specified measurement, control and regulation functions in the process 1, as sensors, by acquiring measured values of process variables and, as actuators, by acting on the process by control interventions. Typical sensors are measuring transducers for level, flow rate, pressure and temperature, analyzers for analyzing gases or liquids and weighing systems. Typical actuators are actuating drives, positioners for valves, other decentralized regulators and frequency converters for electromotive drives for, for example, pumps, heating systems, and/or cooling systems. The automation devices 6, 7, 8, 9 have write and read access to the field devices 10, 11, 12, 13, 14 and thereby control the process 2 in accordance with a control program consisting of a plurality of interacting automation function blocks 16 distributed over the automation devices.

The planning and engineering system 4 contains a planning and engineering software tool 17, such as COMOS from Siemens AG, via which a machine-readable piping and instrumentation flow diagram (P&I) flow diagram 18 is created in which all relevant components of the plant 1 and automation system are identifiable as graphic objects. The properties of the objects are stored in a database 19 in the form of attributes, as are connections between objects in the form of material flows (for example, pipelines) and signal flows (for example, measured values). Furthermore, historical or simulated measurement data from the productive operation of the plant 1 for normal cases and for known fault scenarios are provided in an archive 20 (for example, cloud).

For root cause analysis in the process engineering plant 1, a software tool 21 automatically creates a diagnosable probabilistic model (inference model) of the plant 1 from the existing engineering information on the plant 1, i.e., the planning data for the and the plant structure and component data, which is stored in the plant planning software or can be obtained from data sheets. The inference model enables the probability of occurrence of individual causes of faults to be determined and faulty plant parts or components to be identified by implementing Bayesian inference based on plant measurement data. Here, the software tool 21 is part of the planning and engineering system 4, but it can also run in a separate system.

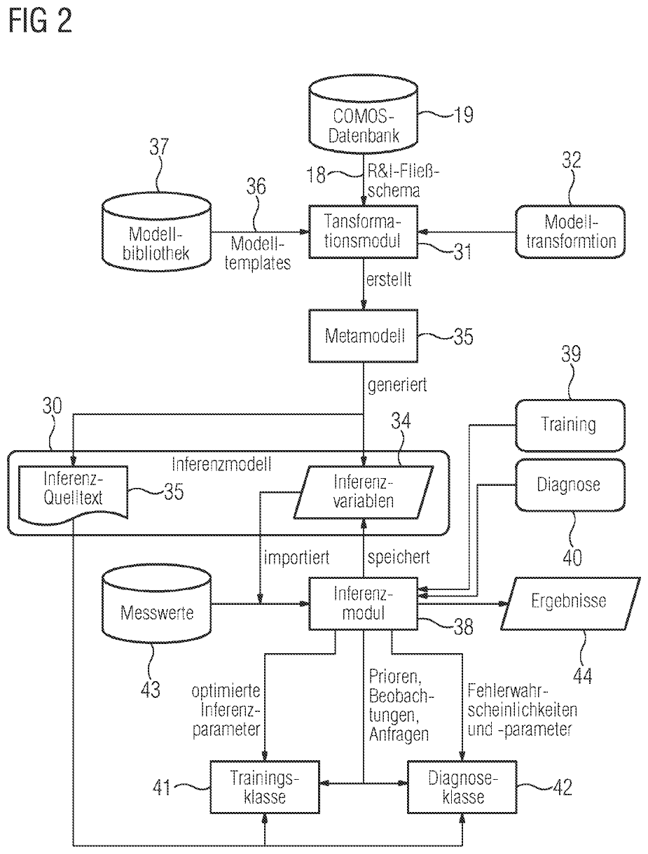

FIG. 2 is a flow diagram showing an example of the basic course of the method in accordance with the invention for root cause analysis. The method consists of a transformation phase, in which the above-mentioned inference model 30 is created, and an inference phase, in which Bayesian inference is performed in order, on the one hand, to train the inference model and, on the other, to determine the probabilities of occurrence of individual causes of faults in the plant 1 and to identify faulty plant parts and components.

In the transformation phase, a transformation module 31 performs a model transformation 32 of the P&I flow diagram 18 of the plant 1 into the inference model 30 with source text 33 required for the inference and variable values 34. Herein, the transformation module 31 reads the P&I flow diagram 18 stored in the COMOS database 19 and first generates a metamodel 35 of the plant 1 by adopting templates 36 from a model library 37. The templates 36 describe the behavior of individual components (for example, pump, valve, tank, and/or pipe) of the plant 1 and contain possible causes of faults (for example, leakage, clogging, and/or reduced pump performance). The model library 37 contains the code to be generated for each component type and the necessary inference variables, i.e., the variables, for which Bayesian inference is to be performed for each component type, so that the inference model 30 of the plant 1 can be generated from the metamodel 35. In principle, the inference code can also be generated directly and without the intermediate step of creating a metamodel.

Inference is implemented in a separate inference module 38 and, for this purpose, can, for example, access the functions of the Infer.NET framework. Infer.NET is an open-source framework written in C# with an interference engine (“InferenceEngine”) containing several algorithms for implementing inference. The basic principle of inference is based on Bayes' theorem:

P(A|B)=[P(B|A)·P(A)]/P(B)

A and B are the events associated with the random variables in the above factor graph. Here, B is an observable effect and A is a hidden cause whose exact probability is unknown. Therefore, P(A) is only an a priori estimate of the sought probability, which is why P(A) is called prior probability. P(B) is the probability of occurrence of the observation B, which can be determined by repeated experiments. P(B|A) is the conditional probability that B is observed when A has occurred. P(B|A) is therefore the factor in the factor graph that establishes the relationship between A and B. The result P(A|B) is the conditional probability that A has occurred when B is observed. P(A|B) is considered to be an improved estimate of P(A) after an observation, which is why it is referred to as the A-posteriori or posterior probability. The more observations are made, the closer the posterior probability approaches the actual probability of occurrence of the cause A. In fault diagnosis, the highest probability of occurrence can be used to infer the most probable cause of a fault.

The inference module 38 has two modes of operation, training 39 and diagnosis 40, which are implemented in two related classes: training class 41 and diagnosis class 42. For both modes of operation, it is first necessary for historical measured values 43, the inference source text 32 and the inference variables 33 to be imported and passed to the respective class in an appropriate form. The training class 41 uses the measured values 43 to optimize the estimates of model parameters (inference parameters) of the inference model 31 representing priors (a priori distributions). These are again stored in the inference model 30, which is the reason why the inference variables 34 and the inference source text 33 are stored separately. In diagnosis 40, inference of the fault probabilities and parameters is performed instead. The results 44 are either output or stored for further processing.

Only the diagnosis of the causes of faults in individual components defined in the templates 36 can occur automatically. Alternatively, further, more complex, causes of faults that do not only affect one component can also be added to the inference model 30. However, this requires the overall model of the plant 1 to be analyzed.

The following explains automatic model transformation by the transformation module 31 in more detail.

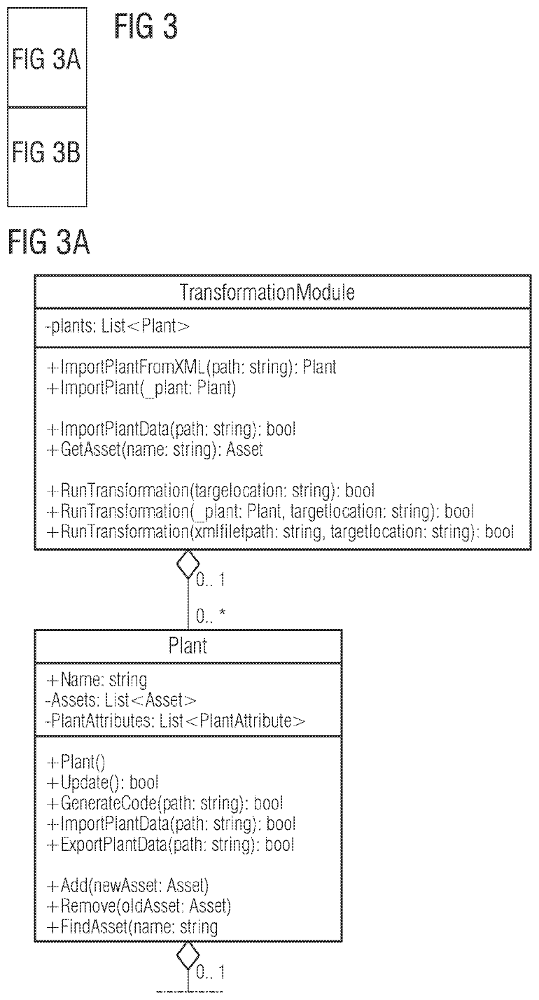

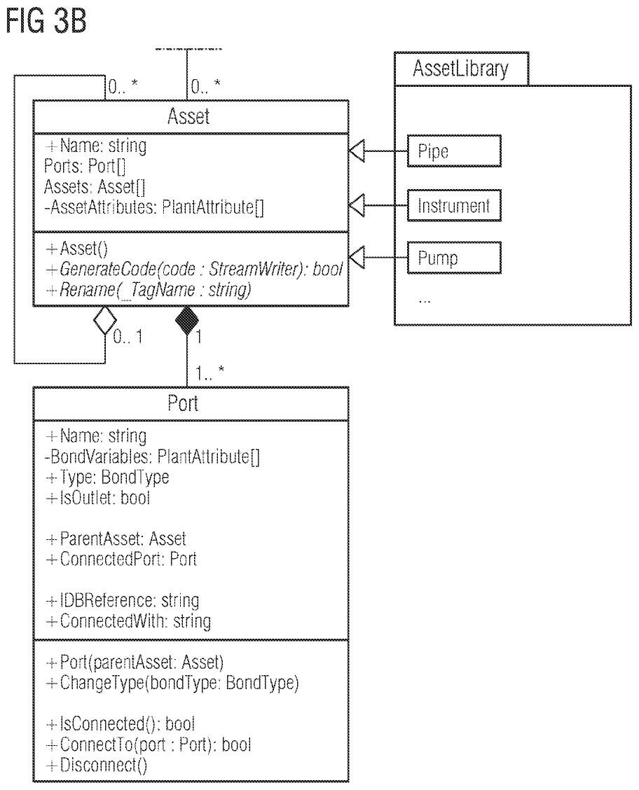

Model transformation 32 is only required once to translate the plant structure 18 and is therefore performed offline separately from root cause analysis 39, 40. FIG. 3 shows an example of the class diagram of the transformation module 31. The transformation consists of a class “TransformationModule” for encapsulation and the metamodel classes “Plant”, “Asset” and “Port” for the plant 1, the components of the plant and their connectors. The component classes for individual components, such as piping, process instrumentation and/or pumps, are collected in a separate “AssetLibrary” (model library 37).

The structure of the metamodel 35 created by the transformation module 31 is intended to emulate the structure of the P&I flow diagram 18 as far as possible to simplify transformation into the inference model 30. While the elements taken from the COMOS database 19 by XML Export only have attributes, the classes of the metamodel 35 additionally contain methods for code generation and model transformation. The attributes of the metamodel 35 are also specially adapted for use as inference variables.

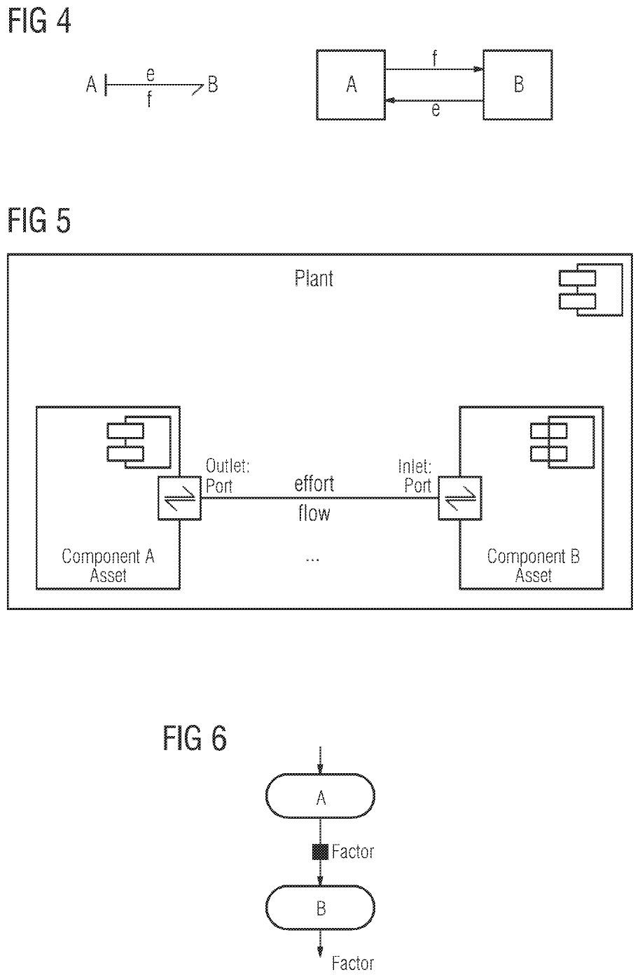

While, in the P&I flow diagram 18, links between the components are primarily used for graphical representation and not for information exchange, the metamodel 35 for generating the inference model 30 needs the links to exchange inference variables. Herein, according to the bond graph theory, the connections are considered to be bidirectional bonds over which any number of variables can be exchanged. Bond graphs are directed graphs that can be used to simulate energy flows. As FIG. 4 shows, using a schematically simplified bond graph (left) with a block diagram (right), the nodes of the graph represent components A, B of the plant and the edges define energy flows by specifying a potential variable e (cause or effort) and a flow variable f (effect or flow) that are multiplicatively linked. The half arrow indicates the direction of the energy flow e·f.

The metamodel 35 checks the energy flow direction and the type of bond, where only ports of the same type can be connected and outputs can only be connected to inputs to avoid misdiagnosis is assured. Different metamodel class methods can then be used to add or remove the translated assets (components) to the plant; ports can be connected to one another or disconnected. This results, for example, in the plant structure of the metamodel 35 of the plant 1 depicted in FIG. 5.

“Plant”, “Asset” and “Port” each have a collection of plant attributes that can be simultaneously converted into inference variables. The plant attributes comprise the physical and/or geometric data for the plant 1, individual components and processed substances, measured variables, fault situations and variables that are only required for the inference. For code generation, the component class is given a recursive method that runs the assets contained in the model library 37 and uses the templates 36 to create the appropriate code for each. When the method has been implemented, the source text file 33 exists, which is included in the inference module 38 and contains the plant-specific inference model 30. After code generation, the list of all collected plant attributes (inference variables) is sorted and exported to a separate file 34.

The variables are mathematical random variables of data types, such as bool, int and double, depending on whether the variable is a switching variable with two values, a discrete (integer) variable or a continuous (floating point number) random variable. A probability distribution is assigned to each value range or value that can be assumed by a variable. Possible probability distributions are, for example, Gaussian or normal distributions for continuous variables, such as many measured variables, Bernoulli distributions for Boolean variables that can only assume the two values and beta distributions for modeling probabilities, such as fault probabilities, which are themselves random variables with distribution functions. In the inference model 30, the random variables are linked to one another by cause-effect relationships or correlations that can be represented by factor graphs. The factor graph shown by way of example in FIG. 6 represents a code line in the form of B=Factor(A) in which the result of the operation Factor on the random variable A is assigned to the random variable B.

As mentioned previously, the inference is performed in the inference module 38, where the functions of the Infer.NET-framework are accessed. To this end, the inference module 38 automatically maps the inference model 30 into a factor graph of the plant 1.

The following is a more detailed explanation of the inference module 38.

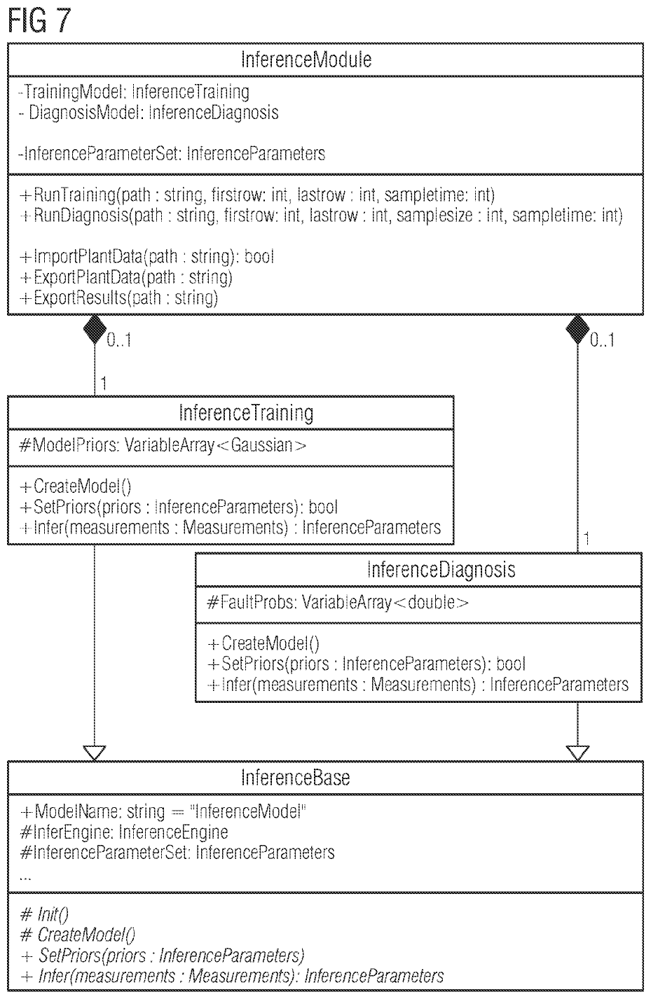

The inference module 38 serves as the starting point for the root cause analysis. The training of the inference model 30 and the diagnosis 40 can be performed as often as desired offline or online and so overhead is avoided by generating the finished inference model 30 once beforehand. The inference module 38 basically consists of four classes, which are shown in detail in a class diagram in FIG. 7. A class “InferenceModule” is used to encapsulate all the functions used and stores the inference variables. A base class “InferenceBase”, which forms the core of the inference module 38 and the function of which is the basis of all other classes, contains all inference methods and the model definition. A diagnosis class “InferenceDiagnosis” and a training class “InferenceTraining” inherit from this class and have only a few changes to adapt to their respective tasks.

The base class contains the four methods Init(), CreateModel(), SetPriors() and Infer(), which are carried out in this sequence.

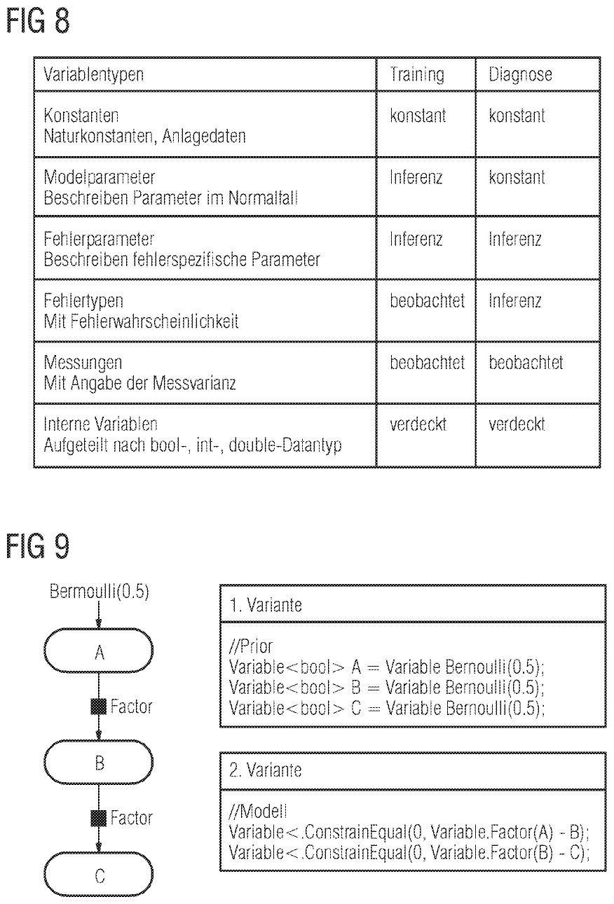

The Init() method initializes the required variables and the Infer.NET inference engine. Several variable types that fulfil various tasks and are listed in FIG. 8 are defined in the model. Each of the variable types has a different function in training and diagnosis.

Constants, for example, remain constant in both cases and contain natural constants and plant parameters that are specified for an inference run.

Model parameters are coefficients of coded mathematical formulas, which are required to describe the normal operation of the plant 1 and are characteristic of this. These parameters can either have a physical meaning, and thus be theoretically calculable, or they have no physical meaning and serve only as a degree of freedom. Infer.NET can perform inference independently of the modeling type and can therefore also be used as a machine learning method. In particular, in the latter case, training with existing measurement data can be necessary because the starting values are usually selected at random and therefore initially deliver poor results. Inference optimizes the existing estimates of the parameters during training so that they better reflect plant behavior after training. If parameters have already been determined, it may be possible to dispense with training if confidence in these parameters is high enough. The meaning of the model parameters can be freely chosen by the programmer and has no influence on the actual inference.

In contrast to the model parameters, the fault parameters describe fault-specific coefficients. In real cases, one and the same fault can have different degrees of severity. Accordingly, it makes sense to perform inference for these parameters both in training and in diagnosis. On the other hand, model parameters should be kept constant in the diagnosis phase.

Every fault type to be identified has its own variable and modeling. Fault types that are not modeled cannot be identified during diagnosis and are likely to be interpreted as a combination of other fault types. Every fault type has a probability that is only calculated in the diagnosis phase. In the training phase, the faults are passed to the system as an observed input variable because, for historical data, faults that have occurred should be known. Otherwise, such data has to be diagnosed.

Measurements are input as observed variables in both training and diagnosis. In addition, a measuring uncertainty should be known for each measured value so that a Gaussian distributed random variable with the correct variance can be determined in the model for each measurement.

The internal variables are intermediate variables in the form of switching variables, integer variables or floating point variables or (bool, int, double). These variables are required as intermediate results or hidden variables within the model and the user does not have direct access to them. They are considered to be variable during inference, but no result distributions are returned.

After initialization in Init ) the model definition occurs in the CreateModel() method of the base class, where the factor graph of the plant 1 is created. The model definition can either be hard-coded in a separate source text file or, as explained above, created by the transformation module 31. The source text file 33 can be exchanged to implement different models. Two approaches are conceivable for the modeling; these are depicted by way of example in FIG. 9.

In the first embodiment, only the Boolean variable A receives the prior distribution Bernoulli(0.5). Variable B is then assigned the result of the operation Factor on variable A. C is assigned the result of the factor of B. This is similar to conventional programming, but, in comparison, Infer.NET allows A to be calculated with this definition A when C is observed. If the ratios between A and C only allow one possible solution, then the prior has hardly any influence on A in this case. In the second embodiment, more use is made of this property of programming. A, B and C are given the same prior distribution so that no bias exists for a specific solution. In the model definition, it is then specified that the result of the operation Factor(A)-B yields zero; in the following line, the same condition for C is specified analogously. This representation is equivalent to the first embodiment for the inference engine and leads to similar results for both directions in both cases. However, in contrast to the first embodiment, in the second embodiment, the lines can be swapped; this represents an enormous advantage for model transformations because it allows the components of the plant to append their code in any order and no special algorithm has to be specified to run the plant.

All prior distributions based on past training runs or plant data are set in the SetPriors() method. The table in FIG. 8 indicates which parameters are set in which phase. Types marked as “constant” are declared as observations in the SetPriors() method because observed variables become constants during inference (cf. 2.3.3). Marking as “observed” means that such variables are only input into the system shortly before the inference query in the Infer() method. These variable types are observed anew with each Infer() call, while the constants specified in SetPriors() remain the same on each inference query, i.e., they provide a constant observation. SetPriors() additionally sets the prior distributions of the model and fault parameters to the Gaussian distributions created from the plant attributes and sets the precision parameters.

Many tasks of the inference module 38 are implemented in the base class. However, in the prior assignment and model creation phase, training and diagnosis differ and so each implements its own CreateModel() method and SetPriors() method. At the beginning of CreateModel() the initialization method of the base class is performed in each case, then their own variables are initialized and prior distributions are assigned. Finally, the CreateModel() method of the base class is performed. In addition to the ModelParameter array and FaultParameter array, the ModelPriors array exists in the training class, FaultPrior array exists in the base class and the FaultProbs array exists in the diagnosis class. The reasons for this division are shown in the table in FIG. 8. Fault probabilities only exist during diagnosis since the occurrence of the faults is observed in the training phase. An inference of the fault probabilities during training would only reflect the relative frequency of the faults during training. However, this is of no interest so no probabilities are determined for training. Likewise, prior distributions for the model parameters only exist in the training phase, since the model parameters are specified in the diagnosis phase. Prior distributions for fault parameters are required in both phases and inference is implemented for these parameters in the base class.

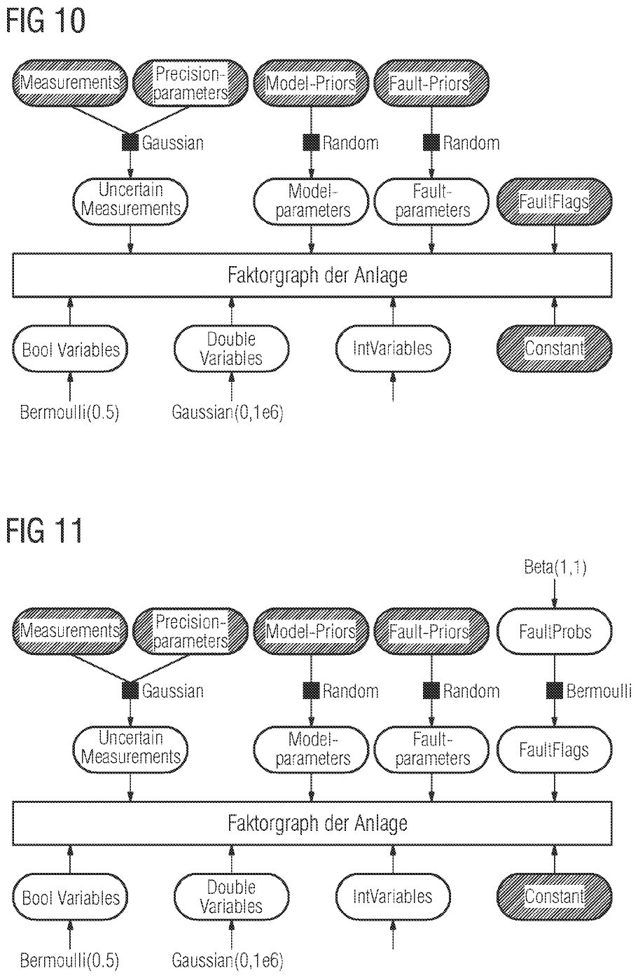

FIG. 10 shows the factor graph of the plant 1 during training. Observed variables are marked in grey, while the values of the variables marked in white can change during inference. Each variable in this factor graph is representative of an array of variables of the same type. Random variables are created from the priors of the model and fault parameters with the aid of Variable.Random; although these random variables are based on the values of priors, they can be freely adapted by the algorithm. The observed faults are input into the model as FaultFlags. Faults that have occurred are given the value true, and those that have not occurred are given the value false. The factor graph of the plant is created in the CreateModel() method of the base class, which contains the inference code created by the transformation module 31. This code may only access the variables defined here and so the plant attributes in the metamodel 35 are assigned a fixed variable type and do not create any new variables of their own.

FIG. 11 shows the factor graph of the plant 1 during diagnosis during which, in contrast to training, the model parameters are observed and cannot be adapted by the inference engine. On the other hand, faults are given their own modeling. These are considered to be Bernoulli distributed random variables with the probabilities FaultProbs. As explained above, the probabilities themselves are specified as beta-distributed and a given a fixed prior. Fault probabilities are only determined for a time slice and not for an entire history. Consequently, all probabilities are reset before each diagnosis, for example, and the inference engine is instead used to correct these probabilities in one direction or the other. The correction difference within the time interval can be used to infer the fault situation. Therefore, it makes sense that all probabilities are initially considered to be equally distributed in order to register this change. The stronger the correction in the direction of 0 or 1, then the more reliable the statement as to whether or not a fault has occurred. If a probability remains at 0.5, then the engine cannot make any statement regarding this fault or the existence of this fault has no effect on the observations made.

The Infer() method performs the inference of the inference model 30. A data structure with the measurements and time stamps are transferred to this method. The values of the measurements, the sampling time and the number of measurements are input as observations of the corresponding model variables. In the case of training, in addition, faults that have occurred are observed. The base class “InferenceBase” implements the inference for the fault parameters, the training class performs the inference for the model parameters and the diagnosis class performs the inference for the fault probabilities. The results are then returned as an InferenceParameterSet. After training, the optimized parameters are stored in the variable database 24.

During diagnosis, the probabilities for all causes of faults are re-estimated. Herein, all causes of faults with probabilities that increase significantly are considered to be actual causes. There are frequently very many causes and in comparison only a few measured variables. Generally, as a consequence, several causes are output, which makes complete sense. Following diagnosis, the results 44 are either output via the console output or exported in table format.

The method in accordance with the invention has several advantages because it combines model-based and signal-based diagnosis methods. For example, model-based methods require high model quality that is difficult to achieve in complex process plants. Likewise, very high measuring accuracy is often required, which increases costs and is one reason why the results of this method are faulty if the measured values are inaccurate. The modeling effort is comparatively low with the method in accordance with the invention and can be reduced still further by training data or changing the modeling. Probabilistic programming enables the measuring accuracy to be included in the diagnosis with little effort and thus high diagnostic accuracy can be achieved despite a small database. Likewise, concurrent faults and faults for which there are no historical records can be identified, which is not possible with signal-based methods. As a rule, the approach used requires much less historical data than comparable signal-based method such as neural networks.

The modeling effort is lower mainly because the model parameters do not have to be exactly measured, calculated or determined in some other way. Instead, it is sufficient to set imprecise initial estimates in the correct order of magnitude. Very precise process parameters are then found via a few training iterations with measurement data. At the same time, Infer.NET specializes in random variables and so no additional modeling of measuring inaccuracies is necessary as in other methods. The identification of new or multiple faults is enabled by the fact that all possible fault states are included in the modeling. A separate category can be programmed for unknown faults. The approach requires less historical data than machine learning methods because it has fewer degrees of freedom for which it is frequently possible to determine good approximations.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

The following publications are cited in this document:
[1.] M. Sayed-Mouchaweh, ed., Fault Diagnosis of Hybrid Dynamic and Complex Systems, Douai: Springer International Publishing AG, 2018
[2.] S. X. Ding, Model-based Fault Diagnosis techniques, Duisburg: Springer-Verlag Berlin Heidelberg, 2008
[3.] G. Niu, Data-Driven Technology for Engineering System Health Management, Shanghai: Springer Nature, 2017
[4.] C. Aldrich and L. Auret, Unsupervised Process Monitoring and Fault Diagnosis with Machine Learning Methods, Stellenbosch: Springer London Heidelberg New York Dordrecht, 2013
[5.] R. Isermann, Fault-Diagnosis System, Darmstadt: Springer-Verlag Berlin Heidelberg, 2006
[6.] C. Aldrich and L. Auret, Unsupervised Process Monitoring and Fault Diagnosis with Machine Learning Methods, Stellenbosch: Springer London Heidelberg New York Dordrecht, 2013

1-7. (canceled)

8. A method for root cause analysis in a process engineering plant, engineering information on the engineering plant, which contains information about the plant components and their interconnection in the engineering plant, being provided in digital form, the method comprising:
creating an inference model from the engineering information to form a probabilistic physical model of the engineering plant with probability distributions and prior variables; and
entering a diagnosis mode of the inference model and performing a Bayesian inference of fault probabilities utilizing measurement data from the engineering plant.

9. The method as claimed in claim 8, wherein the Bayesian inference of the inference model is performed during a training mode of the inference model utilizing measurement data from the engineering plant; and wherein estimates of model parameters representing priors in the inference model are optimized.

10. The method as claimed in claim 8, wherein the inference model is created using a bond graph from the engineering information.

11. The method as claimed in claim 9, wherein the inference model is created using a bond graph from the engineering information.

12. The method as claimed in claim 8, wherein a metamodel of the engineering plant is initially generated from the engineering information on the engineering plant by adopting templates from a model library which contains code to be generated and inference variables for each component type in the engineering plant for which Bayesian inference is to be performed; and wherein the inference model of the engineering plant is created from the metamodel.

13. The method as claimed in claim 9, wherein a metamodel of the engineering plant is initially generated from the engineering information on the engineering plant by adopting templates from a model library which contains code to be generated and inference variables for each component type in the engineering plant for which Bayesian inference is to be performed; and wherein the inference model of the engineering plant is created from the metamodel.

14. The method as claimed in claim 10, wherein a metamodel of the engineering plant is initially generated from the engineering information on the engineering plant by adopting templates from a model library which contains code to be generated and inference variables for each component type in the engineering plant for which Bayesian inference is to be performed; and wherein the inference model of the engineering plant is created from the metamodel.

15. The method as claimed in claim 12, wherein the engineering information on the engineering plant comprises a piping and instrumentation flow diagram (P&I) flow diagram.

16. The method as claimed in claim 14, wherein the engineering information on the engineering plant comprises a piping and instrumentation flow diagram (P&I) flow diagram.

17. The method as claimed in claim 15, wherein the engineering information on the engineering plant comprises a piping and instrumentation flow diagram (P&I) flow diagram.

18. A system for root cause analysis in a process engineering plant, the system comprising:
a processor and memory;
a transformation module which creates an inference model which contains information about components of the engineering plant and interconnection of the components in the engineering plant as a probabilistic physical model of the engineering plant with probability distributions and prior variables from engineering information on the engineering plant; and
an inference module which utilizes measurement data from the engineering plant to perform Bayesian inference of fault probabilities in a diagnosis mode of the inference model.

19. The system as claimed in claim 18, wherein the inference module is further configured to perform Bayesian inference of the inference model; and wherein estimates of model parameters representing priors in the inference model are optimized.

20. A computer program product which is loaded into memory of a computer and which comprises software code sections with which the method according to claim 8 is executed when the computer program product is executed on the computer.
